(19) United States
(12) Patent Application Publication
(10) Pub. No.: US 2010/0081225 A1
(43) Pub. Date: Apr. 1, 2010

(54) MASK PATTERN FOR SELECTIVE AREA GROWTH OF SEMICONDUCTOR LAYER AND SELECTIVE AREA GROWTH METHOD USING THE MASK PATTERN FOR SEMICONDUCTOR LAYER

(75) Inventors: Jung-Ho Song, Daejeon-city (KR); Kisoo Kim, Daejeon-city (KR); Gyungock Kim, Seoul (KR)

Correspondence Address: AMPACC Law Group, 3500 188th Street S.W., Suite 103, Lynnwood, WA, 98037, US

(73) Assignee: Electronics and Telecommunications Research Institute, Daejeon-city (KR)

(21) Appl. No.: 12/517,357

(22) PCT Filed: Oct. 16, 2007
(86) PCT No.: PCT/KR07/05049

§ 371 Date: Jun. 3, 2009

(30) Foreign Application Priority Data
Dec. 5, 2006 (KR) 10-2006-0122569
May 22, 2007 (KR) 10-2007-0049955

(51) Int. Cl. H01L 33/30; B05C 11/00; H01L 21/20

(52) U.S. Cl. 438/46; 118/505; 438/478; 257/E21.09; 257/E33.026

(57) ABSTRACT

Provided is a mask pattern for selective area growth of a semiconductor layer and a selective area growth method for a semiconductor layer for independently controlling a growth rate and a strain of the semiconductor layer. The selective area growth method includes: forming a plurality of pairs of first mask patterns, the first mask patterns in each pair including a first open area therebetween, the first open area having a width that is wider than a distance causing overgrowth of the semiconductor layer, the pairs of the first mask patterns repeatedly arranged with a period P therebetween; wherein controlling a growth rate and a strain of the semiconductor layer formed on the first open area by adjusting the period P.

### TECHNICAL FIELD

The present invention relates to a method of manufacturing a semiconductor device, and more particularly, to a mask pattern used for growing selective areas of a semi-conductor layer and a selective area growth method using the mask pattern for the semiconductor layer.

This work was supported by the IT R&D program of MIC/IITA[2006-S-004-01, Silicon-based high-speed optical interconnection IC].

### BACKGROUND ART

This application claims the benefit of Korean Patent Application No. 10-2006-0122569, filed on Dec. 5, 2006, in the Korean Intellectual Property Office, the disclosure of which is incorporated herein in its entirety by reference.

An optical integrated circuit, in which semiconductor optical devices having different functions from each other are integrated onto a substrate, requires active layers having different structures, for example, different thicknesses and strains from each other. For example, an optical device may require a tensile strained layer. In a compound semi-conductor such as InGaAsP, energy levels of a heavy hole band and a light hole band are changed according to the strain, and also differently react to polarizations of lights. As an example, a polarization insensitive semiconductor optical amplifier requires a weak tensile strained layer.

The active layers having different structures from each other can be grown on one substrate simultaneously using a selective area growth (SAG) method. In the SAG method, a semiconductor substrate is covered by a mask pattern formed of a dielectric thin film to grow the semiconductor layer only on the semiconductor substrate that is exposed by the mask pattern. In particular, the active material on the dielectric thin film can be diffused onto the substrate on which the dielectric thin film is not covered and can participate in the growth in a metal-organic chemical vapor deposition (MOCVD) method. Therefore, the semiconductor layer grown in the region where a relatively large area of substrate is covered with a dielectric thin film becomes thick.

In a semiconductor optical device having a long wavelength (1.3˜1.6 μm wavelength) and using an InP substrate, a quaternary compound InGaAsP is generally used as the active layer, and a band gap and a lattice constant are changed according to a composition ratio of each of the elements. The grown layer (active layer) has a strain due to a difference between the lattice constants of the active layer and the InP substrate.

In the MOCVD method, a thin boundary layer, where the speed of reaction gases is greatly reduced, is formed on the substrate. In the MOCVD process for a general group III-V semiconductor film, the more amount of group V elements As and P are supplied than that of group III elements In and Ga, and thus, a crystal growth speed is determined by a diffusion of the group III elements in the boundary layer (M. Coltrin et al., ‘Mass transport and kinetic limitations in MOCVD selective-area growth,’ Journal of Crystal Growth, vol. 254, pp. 35-45, 2003′). The growth rates of In and Ga become different from each other in the selective area growth due to a difference between the diffusion coefficients of precursors of the In and Ga, and the composition ratios of In and Ga vary from distances from the dielectric thin film.

The selective area growth of the III-V group semiconductor layer that is determined by the diffusion can be modeled by solving a diffusion equation ∇² C(x, z)=0 with appropriate boundary conditions. FIG. 1 is a diagram showing a mask pattern used in the conventional selective area growth of the semiconductor layer and a boundary condition used in the diffusion equation. A mask pattern 2 is formed on a substrate 1, and an open area 3 exists between patterns of the mask pattern 2. A width of the mask pattern 2 is M, and a width of the open area 3 is W. In FIG. 1, C(x, z), D, and k respectively denote a concentration of a precursor of the group III element, a diffusion coefficient, and an incorporation rate into the semiconductor surface.

FIG. 2 is a graph showing a growth rate enhancement of an InGaAsP layer according to the width M of the mask and the distance W between the two masks calculated using the above diffusion equation. The growth rate enhancement is the ratio of the growth rate with respect to the growth rate when the semiconductor layer is grown without using a mask. FIG. 3 is a graph showing the strain of the InGaAsP layer according to the width M of the mask and the distance W between the two masks. The growth rate and the strain of the InGaAsP layer was calculated according to the method disclosed in ‘Alloy composition dependence in selective area epitaxy on InP substrates,’ J. E. Greenspan, Journal of Crystal Growth, vol. 236, pp. 273-280, 2001. In the calculation, the bandgap of the semiconductor layer, that is, the InGaAsP layer, was 1.15 μm, and diffusion coefficients (D/k) of the In and Ga were 40 μm and 150 μm. In FIGS. 2 and 3, when the width M of the mask is increased and the distance W between the masks is reduced, the growth rate of the InGaAsP is increased and the compressive strain is also increased. On the other hand, when the distance W is increased, changes in the growth rate and the compressive strain of the InGaAsP layer according to the increase of the width of the mask are small.

As shown in FIGS. 2 and 3, the increased growth rate and the compressive strain of the semiconductor layer with the narrow open width W and wide width M of the mask has an advantage in that an emission wavelength of the active layer of the optical device can be increased, however, also has the following disadvantages. The crystal in the active layer of the optical device to which the strain is applied cannot be grown to be thicker than a predetermined thickness. That is, if a value obtained by multiplying the thickness of the semiconductor layer with the strain is greater than a critical thickness, the quality of the crystal is degraded and the characteristics of the optical device are also degraded.

Many methods have been suggested to grow semiconductor layers of two active layers that have different structures from each other in order to address the above problems. Suzuki et al. suggested in U.S. Pat. No. 5,543,353, ‘Method of manufacturing a semiconductor photonic integrated circuit,’ that one active area including an open area of a mask be 10˜30 m m, that is, 1˜0.125 times longer than a diffusion distance of a precursor of III-group element and a mask pattern having a width of 16˜800 m m, and the other active area include no mask pattern. The width of the open area must be 10 μm or longer so that arrangement and fabrication processes, such as a waveguide etching process or an electrode deposition process, can be performed easily after the selective area growth. In addition, the width of the open area must be 5 μm or longer so that the strain caused by the lattice mismatch is not excessive. In U.S. Pat. No. 6,239,454, ‘Net strain reduction in integrated laser-modulator,’ Glew et al. suggested that TriMethylGallium that shows high efficiency in the selective area growth is used as a Ga source when a well layer in a quantium well structure is formed, and TriEthylGallium showing a low efficiency in the selective area growth is used as Ga source when a barrier is grown. According to the above method, much strain is applied to the well and less strain is applied to the barrier, and thus, the sum of total strain can be reduced. However, in the methods suggested by Suzuki et al. and Glew et al., it cannot be determined whether the growth rate can be controlled independently of the stress applied the semiconductor layer.

On the other hand, if the width of the open area in the mask is narrow, the quality of crystal in the grown semiconductor layer may not be good. J. Kim et al. showed in the paper ‘Investigation of the substrate-patterning effect on morphological instability in selective area growth,’ Japanese Journal of Applied Physics, Vol. 37, No. 2A, pp. L145-L147, 1998, that an overgrowth at the mask edge makes the surface rough and the roughness of the mask edge propageates and makes entire surface of the selectively grown semiconductor layer rough. Since the optical device is generally located on a center portion of the open area, when the width of the open area is wide, the portion used as the optical device is widely separated from the mask edge and the crystal quality can be improved. However, if the width of the open area is wide, the growth rate and the strain of the semiconductor layer hardly change, and thus, there is no meaning of using the mask.

### DISCLOSURE OF INVENTION

### Technical Problem

The present invention provides a mask pattern for selective area growth, by which a semiconductor layer can be formed while independently controlling a growth rate and a strain without degrading crystal quality.

The present invention also provides a selective area growth method for forming a semiconductor layer while independently controlling a growth rate and a strain of the semiconductor layer without degrading crystal quality.

### Technical Solution

According to an aspect of the present invention, there is provided a mask pattern for selective area growth of a semiconductor layer, the mask pattern including: a plurality of pairs of first mask patterns, the first mask patterns in each pair including a first open area therebetween, the first open area having a width that is wider than a distance causing overgrowth of the semiconductor layer, wherein the first mask patterns are repeatedly arranged with a period P.

The period P may be in the range which can increase a growth rate of the semi-conductor layer formed on the first open area. The period P may be 500 m m or less.

The mask pattern may further include: a second mask pattern on an area besides the first open area. A width of the second mask pattern may have the value in correspondence to a desired growth rate of the semiconductor layer.

The semiconductor layer may be a compound semiconductor layer including two or more group III elements that have different diffusion distances from each other.

According to another aspect of the present invention, there is provided a selective area growth method for a semiconductor layer, the method including: forming a plurality of pairs of first mask patterns, the first mask patterns in each pair including a first open area therebetween, the first open area having a width that is wider than a distance causing overgrowth of the semiconductor layer, the pairs of the first mask patterns repeatedly arranged with a period P therebetween; wherein controlling a growth rate and a strain of the semiconductor layer formed on the first open area by adjusting the period P.

The period P may be 500 μm or less.

According to another aspect of the present invention, there is provided a selective area growth method for a semiconductor layer, the method including: independently controlling a growth rate and a strain of the semiconductor layer formed on a first open area by adjusting widths of a plurality of pairs of first mask patterns, the first open area, and a second mask pattern, wherein the first mask patterns in each pair includes the first open area therebetween that has a width wider than a distance causing overgrowth of the semiconductor layer, and the second mask pattern is formed on an area besides the first open area.

A tensile strain of the semiconductor layer formed on the first open area may be increased by increasing the width of the first open area. A compressive strain of the semiconductor layer formed on the first open area may be increased by reducing the width of the first open area.

The growth rate of the semiconductor layer formed on the first open area may be increased by increasing the number of the second mask patterns. The growth rate of the semiconductor layer formed on the first open area may be increased by increasing the width of the second mask pattern.

The semiconductor layer may include a III-V group compound. The III-V group compound may be InGaAsP.

According to another aspect of the present invention, there is provided a selective growth method for a semiconductor layer for an optical device including a laser area and a modulator area, the method including: forming a plurality of pairs of first mask patterns, the first mask patterns of each pair including a first open area therebetween having a width that is wider than a distance causing overgrowth of the semiconductor layer, and a second mask pattern on an area besides the first open area, on the laser area; and forming a plurality of pairs of third mask patterns, the third mask patterns of each pair including a second open area therebetween having a width that is wider than a distance causing overgrowth of the semiconductor layer, and a fourth mask pattern on an area besides the second open area, on the modulator area, wherein a width of the second mask pattern is thicker than a width of the fourth mask pattern so that the semi-conductor layer on the laser area is thicker than the semiconductor layer on the modulator area.

The semiconductor layer may include a well layer of an active layer. The semi-conductor layer may include InGaAsP.

### ADVANTAGEOUS EFFECTS

According to the present invention, a semiconductor layer can be formed while independently controlling a growth rate and a strain without degrading crystal quality.

### DESCRIPTION OF DRAWINGS

The above and other features and advantages of the present invention will become more apparent by describing in detail exemplary embodiments thereof with reference to the attached drawings in which:

FIG. 1 is a diagram showing a mask pattern used in a selective area growth process for a semiconductor layer and boundary conditions of a diffusion equation according to the conventional art;

FIG. 2 is a graph showing a growth rate enhancement of an InGaAsP layer according to a width of a mask and a distance between masks calculated using the diffusion equation;

FIG. 3 is a graph showing strain of the InGaAsP layer according to the width of the mask and the distance between the masks calculated using the diffusion equation;

FIG. 4 is a diagram showing mask patterns for a selective area growth of a semi-conductor layer, the mask pattern being repeatedly arranged according to an embodiment of the present invention;

FIG. 5 is a graph showing the enhancement in a growth rate and a change of a strain of a semiconductor layer according to a change in a period P of the mask pattern shown in FIG. 4;

FIGS. 6A through 6C are diagrams showing mask patterns used to calculate changes of the growth rate and the strain of the semiconductor layer; and

FIG. 7 is a graph showing a spatial distribution of Ga and In in the selective area growth process of FIG. 4.

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being ‘on’ another layer or substrate, it can be directly on the other layer or substrate, or intervening layers may also be present. Like reference numerals in the drawings denote like elements.

FIG. 4 is a diagram showing mask patterns for a selective area growth of a semi-conductor layer, the mask pattern having a repeated arrangement according to an embodiment of the present invention. In addition, a window for calculating a diffusion equation like that described with reference to FIG. 1 is shown in FIG. 4. Referring to FIG. 4, pairs of mask patterns 20 are repeatedly arranged with a predetermined period P of about 500 μm or less on a semiconductor substrate 10. An open area 22 exists between each two mask patterns 20. The growth rate of the semiconductor layer can be increased to a desired level while changing the strain within a range of the period P. The range of the period P can be calculated as follows.

A semiconductor layer is grown on the semiconductor substrate 10 in the open area 22 that is exposed between the mask patterns 20 using a selective area growth. In the current embodiment, an InGaAsP layer, that is, a group III-V compound semi-conductor, is grown on an InP substrate. The selective area growth is performed by a diffusion of a material, and the growth rate and a strain of the semiconductor layer can be modeled by a diffusion equation using appropriate boundary conditions. In the mask patterns of FIG. 4, because the open area 22 is repeated, the boundary condition of the diffusion equation can be dC/dx=0. In FIG. 4, a distance between two adjacent open areas 22 is the period P.

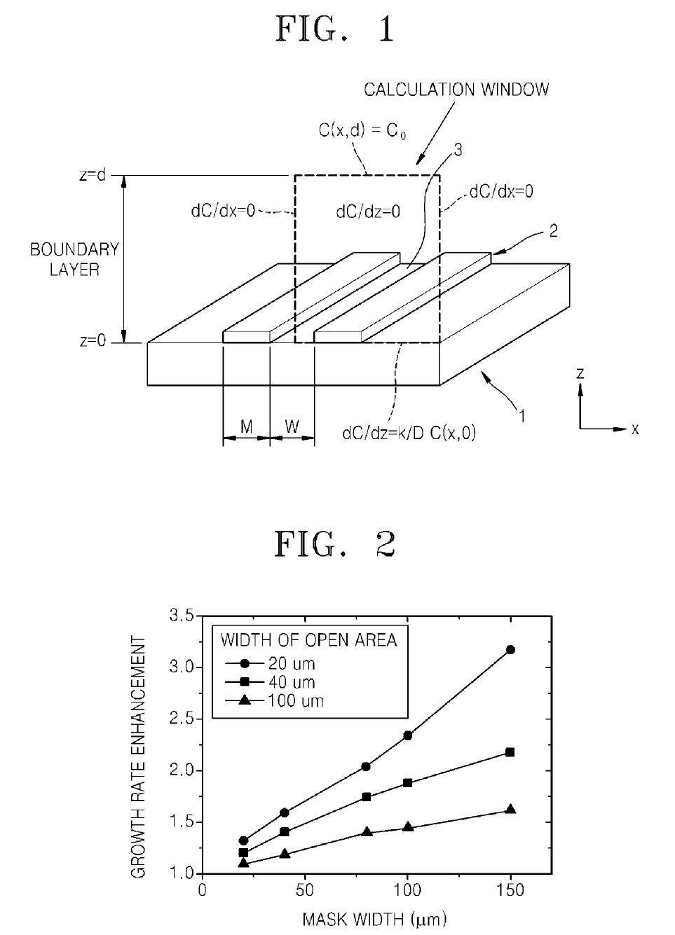

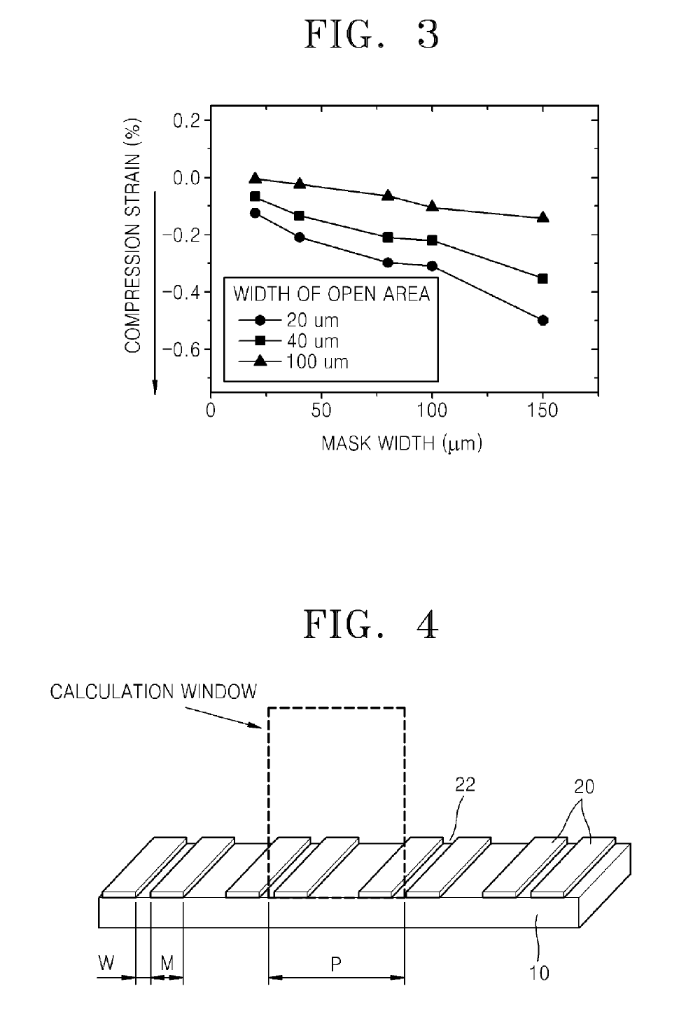

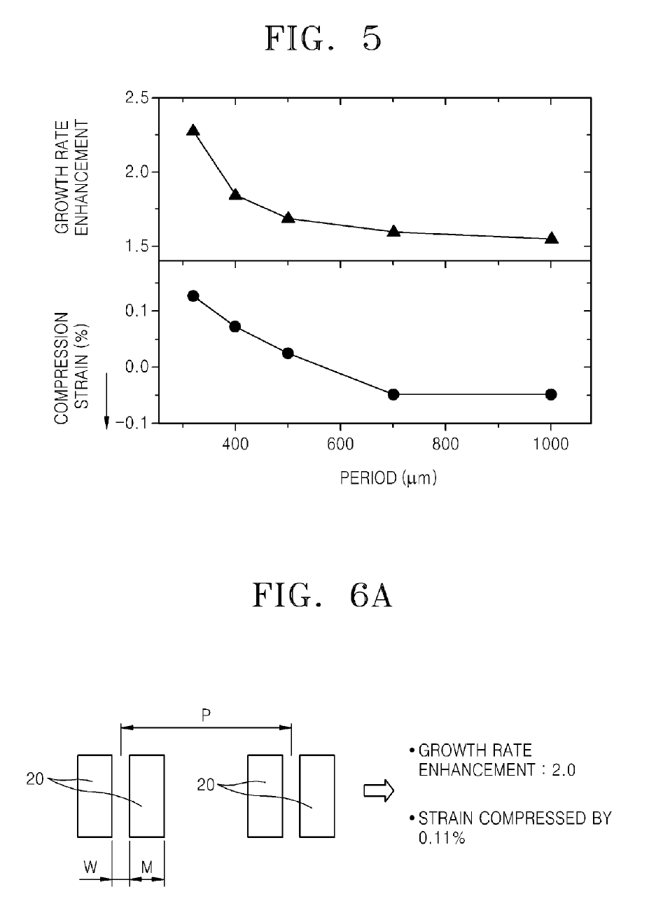

FIG. 5 is a graph showing changes in a growth rate increase and the strain of the semiconductor layer, which are calculated while changing the period P as defined in FIG. 4. In the current embodiment, a width of the mask pattern 20 and a width of the open area 22 are equal to 100 μm. The width of the open area 22 is greater than a diffusion constant of a precursor of the semiconductor layer, and thus, greater than a distance generated by overgrowth of the semiconductor layer. According to FIG. 5, when the period P increases, the growth rate increase of the semiconductor layer is reduced and the compressive strain is increased. This is because that the growth rate and the strain of the semiconductor layer are affected by adjacent mask patterns when the period P is reduced. According to the conventional art, the period P is sufficiently greater than the width M of the mask pattern 20 or the width W of the open area 22, and thus, the mask patterns 20 adjacent to the optical device less affect the selective area growth. In the current embodiment, since the width of the open area 22 is appropriately large so that overgrowth of the semiconductor layer does not occur, the crystal quality can be maintained while improving the growth rate of the semi-conductor layer. When the graph of FIG. 5 is compared with the graphs of FIGS. 2 and 3, even though the widths of the open areas 22 and the mask patterns 20 are the same, that is, 100 μm, the growth rate enhancement of the semiconductor layer of the current embodiment is greater than that of the conventional art and the change of the strain of the current embodiment is smaller than that of the conventional art. That is, in the current embodiment, when the period P is reduced, the growth rate of the semi-conductor layer can be increased without reducing the width of the open area 22, and thus, the degradation of the crystal quality of the semiconductor layer, which is caused by the overgrowth due to the reduction of the width of the open area 22, can be prevented. Therefore, the growth rate of the semiconductor layer can be increased to the desired level with an allowable change in the strain by reducing the period P. On the other hand, as shown in FIG. 5, the period P, by which the growth rate of the semi-conductor layer is increased, is about 500 μm or less.

In another embodiment of the current embodiment, the use of an additional (dummy) mask pattern besides the mask patterns 20 for forming the device and the adjustment of the width of the open area 22 independently control the thickness of the semiconductor layer and the strain.

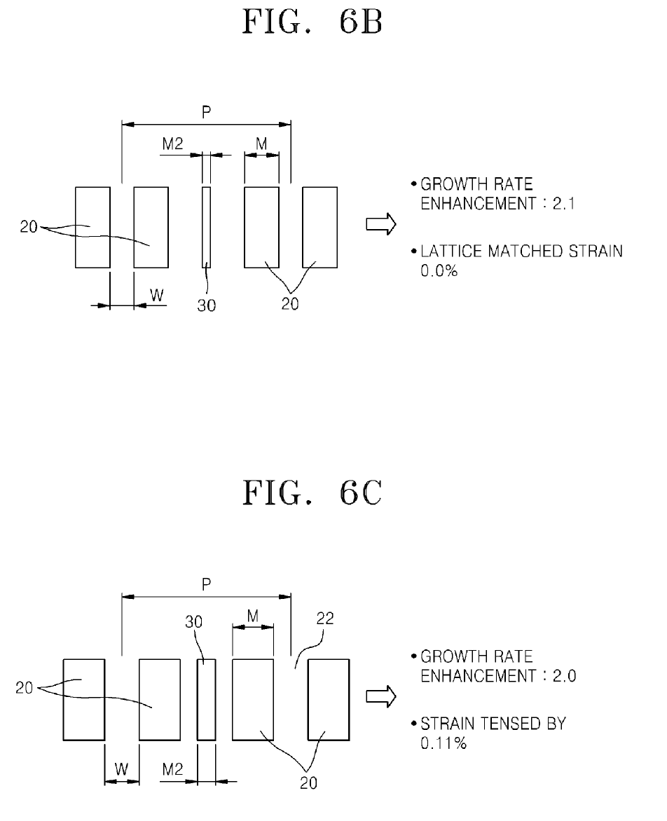

FIGS. 6A through 6C are diagrams showing mask patterns used to calculate the changes in the growth rate and the strain of the semiconductor layer. According to the current embodiment, the InGaAsP layer, that is, group III-V compound semiconductor, is grown on an InP substrate like in the embodiment shown in FIGS. 4 and 5. The periods P in FIGS. 6A through 6C are the same, that is, 500 μm, and the width of the open area 22 between the patterns 20 is 50 μm or greater, and is thus large enough not to generate the overgrowth of the InGaAsP layer. The growth rate enhancement and the strain of the InGaAsP layer were calculated with respect to the growth rate and the strain of the InGaAsP layer that is grown without using the mask patterns.

First, the mask pattern 20 in FIG. 6A has a period P of 500 μm, the pattern 20 for forming the device has a width of 100 μm, the open area 22 has a width of 50 μm, and an additional pattern is not used. In the case of the mask pattern of FIG. 6A, the growth rate enhancement of the InGaAsP layer is 2.1 and the compressive strain of 0.11%. In FIG. 6A, the growth rate of the InGaAsP layer increases twice, however, the compressive strain is not excessively increased. The mask pattern of FIG. 6B has a period P of 500 μm, the pattern 20 for forming the device having a width of 110 μm, the open area 220 has a width of 70 μm, and a width of an additional pattern 30 has a width of 40 μm. In the case of the mask pattern in FIG. 6B, the growth rate enhancement of the InGaAsP layer is 2.1 and the strain is 0%. That is, the growth rate of the InGaAsP layer is increased twice without increasing the strain. The mask pattern of FIG. 6C has a period P of 500 μm, the pattern 20 for forming the device has a width of 110 μm, the open area 22 has a width of 110 μm, and the additional pattern 30 has a width of 80 μm. In the case of the mask pattern of FIG. 6C, the growth rate enhancement of the InGaAsP layer is 2.0 and a tensile strain is 0.11%. That is, the growth rate enhancement of the InGaAsP layer is increased twice while increasing the tensile strain a little.

By changing the mask pattern as shown in FIGS. 6A through 6C, the InGaAsP layer can be selectively grown with a growth rate increased more than twice, a compressive strain of 0.1%, a strain of 0%, and a tensile strain of 0.1%. The above result is because the growth rate of the InGaAsP layer by the selective crystal growth increases when a fill factor of the mask pattern increases, and the diffusion coefficients of the precursors of group III elements are different from each other.

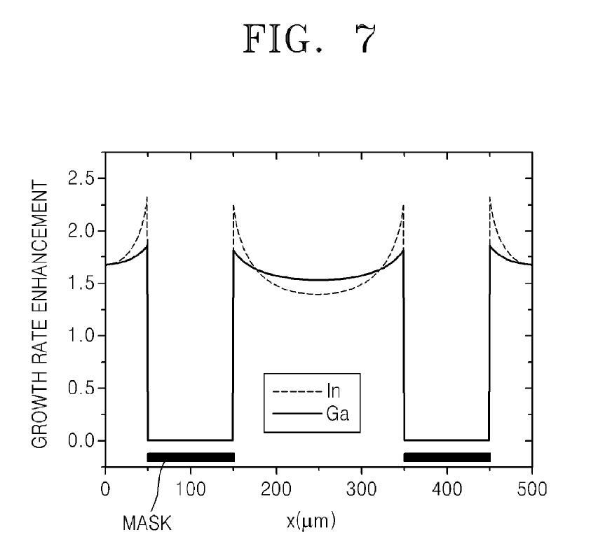

FIG. 7 is a graph showing spatial distributions of Ga and In in the selective area growth process of FIG. 4. In having a small diffusion coefficient grows thicker on boundaries of the mask, and Ga having a large diffusion coefficient grows thicker on a portion apart from the mask. In the InGaAsP material, if more In exists more than the lattice matched condition, the compressive strain is applied, and if more Ga exists, more, the tensile strain is applied. Therefore, the strain of the grown InGaAsP layer is determined according to the number of boundaries between the layer and the mask, and the distance from the portion where the InGaAsP layer is formed to the boundary of the mask. In order to increase the number of boundaries, the mask having a large width can be divided into a plurality of small masks (refer to FIGS. 6B and 6Q. When the additional pattern 30 is used as shown in FIGS. 6B and 6C, the boundaries of the mask increase, and the boundaries of the mask are separated from the open area 22, and thus, the compressive strain of the InGaAsP layer on the open area 22 can be reduced. The growth rate enhancement of the selective crystal growth is increased when the fill factor of the mask pattern increases, and thus, the width of the mask pattern can be increased while maintaining the number of the additional mask patterns in a period P or the number of patterns can be increased by reducing the period P to increase the thickness of the layer. In the current embodiment, the growth conditions of the InGaAsP layer are described, however, the present invention can be applied to other kinds of semiconductor layers.

Selective area growth described above can be applied to forming optical integrated circuit, for example, optical device including laser area and modulator area. To grow semiconductor layer of the laser area thicker than that of the modulator area, width of additional pattern in the laser area can be larger than that in the modulator area in the mask pattern. The semiconductor layer of the optical device can include well layer of the active layer, and can comprise InGaAsP. According to the present invention, the width of the open area between the mask patterns, on which the device is formed, is wide enough not to generate overgrowth, and at the same time, the period P of the mask pattern is reduced. Thus, the growth rate of the semiconductor layer can be increased to a desired level while changing the strain within an allowable range.

In addition, the growth rate of the semiconductor layer can be controlled by using the additional mask pattern to adjust the fill factor of the mask pattern, and the strain of the semiconductor layer can be controlled by controlling the width of the open area while maintaining the width, by which overgrowth of the semiconductor layer is not generated. Therefore, the growth rate and the strain of the semiconductor layer can be independently controlled.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

The present invention can be applied for semiconductor optical devices having different functions from each other which are integrated onto a substrate.

1. A mask pattern for selective area growth of a semiconductor layer, the mask pattern comprising:
a plurality of pairs of first mask patterns, the first mask patterns in each pair including a first open area therebetween, the first open area having a width that is wider than a distance causing overgrowth of the semiconductor layer, wherein the first mask patterns are repeatedly arranged with a period P.

2. The mask pattern of claim 1, wherein the period P is in the range which can increase a growth rate of the semiconductor layer formed on the first open area.

3. The mask pattern of claim 2, wherein the period P is 500 μm or less.

4. The mask pattern of claim 1, further comprising:
a second mask pattern on an area besides the first open area.

5. The mask pattern of claim 4, wherein a width of the second mask pattern has the value in correspondence to a desired growth rate of the semiconductor layer.

6. The mask pattern of claim 1 or claim 4, wherein the semiconductor layer is a compound semiconductor layer including two or more group III elements that have different diffusion distances from each other.

7. A selective area growth method for a semiconductor layer, the method comprising:
forming a plurality of pairs of first mask patterns, the first mask patterns in each pair including a first open area therebetween, the first open area having a width that is wider than a distance causing overgrowth of the semiconductor layer, the pairs of the first mask patterns repeatedly arranged with a period P therebetween; wherein controlling a growth rate and a strain of the semiconductor layer formed on the first open area by adjusting the period P.

8. The selective area growth method of claim 7, wherein the period P is 500 μm or less.

9. A selective area growth method for a semiconductor layer, the method comprising:
independently controlling a growth rate and a strain of the semiconductor layer formed on a first open area by adjusting widths of a plurality of pairs of first mask patterns, the first open area, and a second mask pattern, wherein the first mask patterns in each pair includes the first open area therebetween that has a width wider than a distance causing overgrowth of the semiconductor layer, and the second mask pattern is formed on an area besides the first open area.

10. The selective area growth method of claim 9, wherein a tensile strain of the semiconductor layer formed on the first open area is increased by increasing the width of the first open area.

11. The selective area growth method of claim 9, wherein a compressive strain of the semiconductor layer formed on the first open area is increased by reducing the width of the first open area.

12. The selective area growth method of claim 9, wherein the growth rate of the semiconductor layer formed on the first open area is increased by increasing the number of the second mask patterns.

13. The selective area growth method of claim 9, wherein the growth rate of the semiconductor layer formed on the first open area is increased by increasing the width of the second mask pattern.

14. The selective area growth method of claim 9, wherein the semiconductor layer includes a group III-V compound.

15. The selective area growth method of claim 14, wherein the group III-V compound is InGaAsP.

16. A selective growth method for a semiconductor layer for an optical device including a laser area and a modulator area, the method comprising:
forming a plurality of pairs of first mask patterns, the first mask patterns of each pair including a first open area therebetween having a width that is wider than a distance causing overgrowth of the semiconductor layer, and a second mask pattern on an area besides the first open area, on the laser area; and
forming a plurality of pairs of third mask patterns, the third mask patterns of each pair including a second open area therebetween having a width that is wider than a distance causing overgrowth of the semiconductor layer, and a fourth mask pattern on an area besides the second open area, on the modulator area, wherein a width of the second mask pattern is thicker than a width of the fourth mask pattern so that the semiconductor layer on the laser area is thicker than the semiconductor layer on the modulator area.

17. The selective area growth method of claim 16, wherein the semiconductor layer includes a well layer of an active layer.

18. The selective area growth method of claim 16, wherein the semiconductor layer includes InGaAsP.
